(19) United States
(12) Patent Application Publication
(10) Pub. No.: US 2006/0092048 A1
(43) Pub. Date: May 4, 2006

(54) Semiconductor device

(75) Inventors: Kosuke Nishio, Osaka (JP); Seigo Suguta, Osaka (JP); Yoshiki Matsumoto, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/187,959

(22) Filed: Jul. 25, 2005

(30) Foreign Application Priority Data
Oct. 28, 2004 (JP) 2004-313478

(51) Int. Cl. H03M 7/00

(52) U.S. Cl. 341/50

(57) ABSTRACT

The present invention provides a semiconductor device with which it is possible to easily realize an information processing function according to an intended application while it is possible to suppress an increase in the management costs when, for example, making a change to the function, wherein a processing function setting section stores information unique to the semiconductor device, e.g., the product number or the version number of the semiconductor device, as information that indicates which one of a plurality of processing functions of a processing section should be enabled. A processing function control section performs a function control operation so that a predetermined processing function of the processing section is enabled according to information stored in the processing section.

### CROSS REFERENCE TO RELATED APPLICATION

This Nonprovisional application claims priority under 35 U.S.C. §119(a) on Patent Application No. 2004-313478 filed in Japan on Oct. 28, 2004, the entire contents of which are hereby incorporated by reference.

### BACKGROUND OF THE INVENTION

1. Field of the Invention

The present invention relates to a semiconductor device having a plurality of processing functions, such as encoding and decoding, to be performed on image data and sound data, for example, wherein the semiconductor device selectively performs one of the processing functions on the input data.

2. Description of the Background Art

Image data and sound data are processed into digital data, compressed through a high-efficiency encoding process into data of a smaller amount of information, and multiplexed, and the obtained data is recorded on a recording medium such as a DVD (Digital Versatile Disc) disc or transferred in digital TV broadcast or via the Internet. For example, data compression formats for image data include MPEG-2 (Moving Picture Experts Group) and MPEG-4, and those for sound data include Dolby Digital, DTS (Digital Theater System), MPEG Audio, MPEG AAC (Advanced Audio Coding), Packed PCM being a lossless encoding format, and a PCM format with which the amount of information is not reduced (Dolby Digital is a registered trademark of Dolby Laboratories, Inc. of United States of America, and DTS is a registered trademark of DTS of United States of America).

There are various schemes for encoding image data and sound data so as to comply with the applications mentioned above. For example, a DVD recorder for encoding and recording image data, etc., and a DVD player for decoding and reproducing image data, etc., recorded on a DVD disc include a semiconductor device having an encoding/decoding function according to the application thereof.

FIG. 1 is a block diagram showing a configuration of a conventional semiconductor device 400 as described above. Referring to FIG. 1, the semiconductor device 400 includes an input section 401, a processing section 402 and an output section 403, and decodes a signal recorded on a DVD disc, for example, to output the decoded signal to an external unit outside the semiconductor device 400.

The input section 401 receives a signal recorded on a DVD disc that has been encoded and multiplexed.

As part of its processing function, the processing section 402 functions as an AV decoding section for decoding a signal from the input section 401 into image data and sound data by a predetermined decoding function.

The output section 403 outputs the image data and the sound data decoded by the processing section 402 to an external unit outside the semiconductor device 400.

In the semiconductor device 400 as described above, a required encoding/decoding operation is realized by, for example, replacing an existing encoding/decoding program with another.

Some semiconductor devices include therein all or some of those programs.

The use of a scheme for encoding/decoding image data or sound data may sometimes require a license from the developer of that scheme, and a program in a semiconductor device may be deleted or modified depending on the application of the semiconductor device.

Some semiconductor devices have a password authentication function so that only an authorized user can use the semiconductor device to perform an encoding operation, etc. (see, for example, Japanese Laid-Open Patent Publication No. 5-56035).

However, the number of encoding schemes for image data and sound data has increased, and the variety of applications of the semiconductor device has also increased, whereby there is an increased number of combinations of encoding schemes, etc., for image data and sound data. Therefore, with a semiconductor device of the type that realizes an encoding operation, etc., according to the application of the semiconductor device by replacing, deleting or modifying programs, if a program for performing an encoding operation, etc., is to be provided in an internal ROM, it will be necessary to newly develop a semiconductor device according to a necessary encoding scheme, etc. Even if the program is not to be provided in an internal ROM, it will be necessary to modify the overall configuration of the processing section.

A semiconductor device of the type that employs password authentication for authorizing the use of the semiconductor device does not have a configuration such that an encoding operation, etc., is realized according to the application of the semiconductor device, and it will be necessary to newly develop a semiconductor device according to the application thereof.

Therefore, if, for example, a change needs to be made to part of a program for making a change to the function of an encoding operation, etc., it will be necessary to make the change and verify the normal operation of the new function for each of a plurality of types of semiconductor devices (processing sections) that have the particular encoding function, thus increasing the management costs.

### SUMMARY OF THE INVENTION

In view of the problems set forth above, it is an object of the present invention to provide a semiconductor device, with which it is possible to easily realize an information processing function according to an intended application while it is possible to suppress an increase in the management costs when, for example, making a change to the function.

In order to achieve the object set forth above, the present invention provides a semiconductor device including circuits formed on a semiconductor substrate, including: a processing section having a plurality of information processing functions; and a function control section for performing a function control operation so that at least one of the plurality of information processing functions of the processing section is enabled or disabled according to device identification information stored in the semiconductor device for identifying the semiconductor device.

In one embodiment of the invention, the device identification information is a product number or a version number of the semiconductor device.

Thus, it is possible to perform the function control operation so that at least one of the plurality of information processing functions of the processing section is enabled according to the internal state of the semiconductor device.

In one embodiment of the invention, the present invention provides a semiconductor device including circuits formed on a semiconductor substrate, including: a processing section having a plurality of information processing functions; and a function control section for performing a function control operation so that at least one of the plurality of information processing functions of the processing section is enabled or disabled according to function permission information that is input from outside the semiconductor device while being encrypted at least partially.

Thus, it is possible to control the functions of the processing section according to the function permission information that is input from outside the semiconductor device while being encrypted. Since the function permission information is encrypted, it is possible to prevent an unauthorized use of a predetermined information processing function the use of which is being restricted.

In one embodiment of the invention, the function control section performs the function control operation based on authentication data stored in advance in the semiconductor device and the function permission information.

Thus, it is possible to determine whether or not input function permission information is valid, whereby it is possible to perform the function control operation so that at least one of the plurality of information processing functions of the processing section is enabled or disabled according to valid function permission information.

In one embodiment of the invention, the function permission information contains function identification information for identifying at least one of the plurality of information processing functions; and the function control section enables at least one of the plurality of information processing functions of the processing section according to the function identification information.

Thus, it is possible to specify which information processing function should be enabled or disabled.

In one embodiment of the invention, the present invention provides a semiconductor device including circuits formed on a semiconductor substrate, including: a processing section having a plurality of information processing functions; a function control section for performing a function control operation so that at least one of the plurality of information processing functions of the processing section is enabled or disabled according to function permission information that is transmitted from outside the semiconductor device; and a communications section for transmitting device identification information for identifying the semiconductor device to outside the semiconductor device and for receiving function permission information transmitted from outside the semiconductor device according to the device identification information, wherein the function control section performs the function control operation according to the function permission information received by the communications section.

Thus, it is possible to control the functions of the processing section according to information that is received from outside the semiconductor device by means of communications. If the semiconductor device is identified by using the device identification information for specifying the semiconductor device, it is possible to prevent an unauthorized use of the function control operation for enabling/disabling at least one of the plurality of information processing functions of the processing section.

In one embodiment of the invention, at least a portion of the function permission information is encrypted.

In one embodiment of the invention, key information used for encrypting the function permission information or for decrypting the encrypted function permission information is fixedly predetermined key information or is a part or whole of a program included in the processing section.

Thus, since the function permission information is encrypted, it is possible to prevent an unauthorized use of a predetermined information processing function the use of which is being restricted.

In one embodiment of the invention, the information processing functions include at least one of an encoding operation and a decoding operation.

Thus, it is possible to perform a function control operation so that at least one of a plurality of information processing functions, including an encoding operation or a decoding operation, is enabled or disabled according to the information for specifying the semiconductor device or the function permission information.

### BRIEF DESCRIPTION OF THE DRAWINGS

FIG. 1 is a block diagram showing a configuration of a conventional semiconductor device.

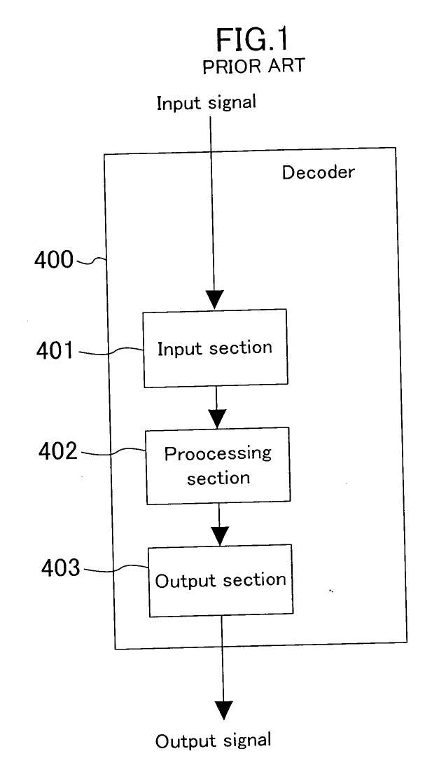

FIG. 2 is a block diagram showing a configuration of a semiconductor device according to Embodiment 1 of the present invention.

FIG. 3 is a block diagram showing a configuration of a semiconductor device according to Embodiment 2 of the present invention.

FIG. 4 is a block diagram showing a configuration of a semiconductor device according to Embodiment 3 of the present invention.

### DETAILED DESCRIPTION OF THE PREFERRED EMBODIMENTS

Preferred embodiments of the present invention will now be described. These embodiments are each directed to a semiconductor device including circuits formed on a semiconductor substrate for use in a DVD player for reproducing a signal encoded and recorded on a DVD disc, wherein the semiconductor device decodes the encoded signal.

### Embodiment 1

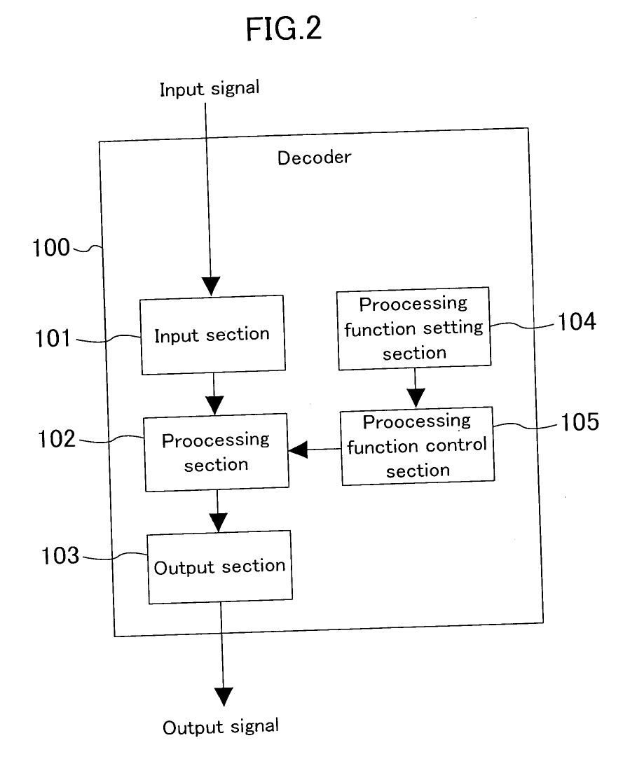

FIG. 2 is a block diagram showing a configuration of a semiconductor device 100 according to Embodiment 1 of the present invention. Referring to FIG. 2, the semiconductor device 100 includes an input section 101, a processing section 102, an output section 103, a processing function setting section 104 and a processing function control section 105, and decodes an input signal while performing a function control operation so that at least one of a plurality of decoding functions of the processing section 102 is enabled according to the internal state of the semiconductor device 100.

The input section 101 receives an encoded, multiplexed signal recorded on a DVD disc, and outputs the input signal to the processing section 102.

As part of its processing function, the processing section 102 functions as an AV decoding section having Decoding Function 1 and Decoding Function 2 for decoding input image data, etc., wherein at least one of Decoding Function 1 and Decoding Function 2 is enabled according to a control signal from the processing function control section 105, and if a decoding function corresponding to the input signal from the input section 101 is enabled, the input signal is decoded into image data and sound data by the decoding function.

Decoding Function 1 and Decoding Function 2 of the processing section 102 may be all hardware, all software, or a combination thereof.

The output section 103 outputs the image data and the sound data decoded by the processing section 102 to an external unit outside the semiconductor device 100.

The processing function setting section 104 stores information that identifies the semiconductor device 100. Specifically, the processing function setting section 104 stores, for example, a value in the version register, the product number of the semiconductor device, or the like.

The processing function control section 105 performs a function control operation so that at least one of Decoding Function 1 and Decoding Function 2 of the processing section 102 is enabled according to the value stored in the processing function setting section 104. For example, Decoding Function 1 and Decoding Function 2 are both enabled if the value stored in the processing function setting section 104 is “1”, while only Decoding Function 1 is enabled otherwise.

With the semiconductor device 100 having such a configuration, an input signal is decoded into image data and sound data as follows.

The processing function control section 105 performs a control operation so that a decoding function of the processing section 102 (e.g., Decoding Function 1) is enabled according to the information stored in the processing function setting section 104. If the input signal is a signal to be decoded by Decoding Function 1, the processing section 102 decodes the input signal into image data and sound data, which are output via the output section 103 to an external unit outside the semiconductor device 100.

Thus, with the semiconductor device 100 of the present embodiment, it is possible to realize a decoding function, etc., according to an intended application only by changing the information that identifies the semiconductor device 100 without changing the configuration of the processing section 102. Therefore, the configuration of the processing section 102 can be used universally, eliminating the need to develop a new processing section for each application. Thus, when it is necessary to make a change to part of the decoding function of the processing section, it is only required to make the change and verify the normal operation of the new function for only one type of processing section, suppressing an increase in the management costs when, for example, making a change to the function.

### Embodiment 2

A semiconductor device 200 according to Embodiment 2 of the present invention is an example of a semiconductor device performing a function control operation as described above. However, as opposed to Embodiment 1, the control of the function of the processing section is performed not based on the internal state of the semiconductor device, but based on information from outside the semiconductor device. Note that in this and subsequent embodiments, like elements to those of Embodiment 1 will be denoted by like reference numerals, and will not be further described below.

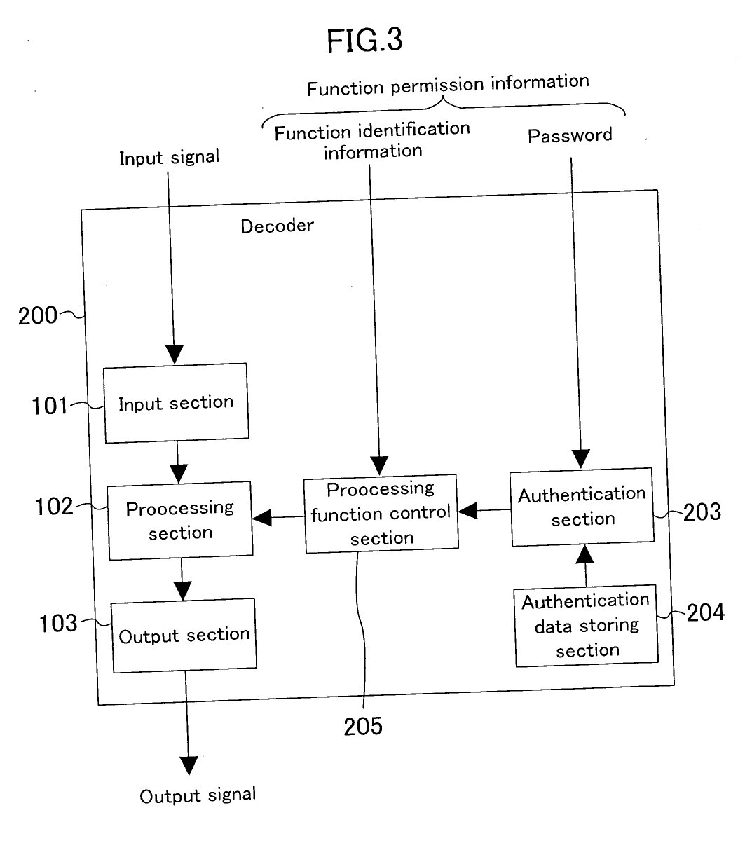

Referring to FIG. 3, the semiconductor device 200 includes the input section 101, the processing section 102, the output section 103, an authentication section 203, an authentication data storing section 204 and a processing function control section 205. At least one of a plurality of decoding functions of the processing section 102 is enabled according to function permission information to be described later that is input from outside the semiconductor device 200, and if a decoding function corresponding to the input image data, etc., is enabled, the semiconductor device 200 decodes an input signal by the decoding function.

The function permission information contains function identification information that indicates which decoding function of the processing section 102 should be enabled/disabled, and a password for permitting the function control operation to be performed.

The function identification information is data that indicates which decoding function of the processing section 102 should be enabled, and is input to the semiconductor device 200 while being encrypted. By setting the amount of information to be greater than the number of decoding functions of the processing section 102, a user is prevented from easily making an unauthorized use of a decoding function for purposes other than the intended application. The key information used for the encryption (decryption) may be predetermined information, or may be varied depending on the configuration of the processing section 102. For example, if the decoding function of the processing section 102 is implemented by software provided in a ROM, a part or whole of the software may be used as the key information.

The authentication section 203 determines whether or not the password contained in the input function permission information is valid based on the authentication data stored in the authentication data storing section 204. If the password is valid, the authentication section 203 outputs an operation permission signal to the processing function control section 205.

If the operation permission signal is received from the authentication section 203, the processing function control section 205 decrypts the function identification information contained in the function permission information, and performs a function control operation based on the decrypted function identification information so that at least one of Decoding Function 1 and Decoding Function 2 of the processing section 102 is enabled. For example, Decoding Function 1 and Decoding Function 2 are both enabled if the value of the decrypted function identification information is “1”, and only Decoding Function 1 is enabled otherwise.

With the semiconductor device 200 having such a configuration, an input signal is decoded into image data and sound data as follows.

The authentication section 203 compares the password contained in the input function permission information with the authentication data stored in the authentication data storing section 204, and if it is determined that the password is valid, the authentication section 203 outputs the operation permission signal to the processing function control section 205. If the processing function control section 205 receives the operation permission signal, the processing function control section 205 decrypts the function identification information, and controls the processing section 102 so that a decoding function of the processing section 102 (e.g., Decoding Function 1) is enabled according to the value of the decrypted function identification information. If the input signal is a signal to be decoded by Decoding Function 1, the processing section 102 decodes the input signal into image data and sound data, which are output via the output section 103 to an external unit outside the semiconductor device 200.

As described above, also with the present embodiment, it is possible to realize a decoding function, etc., according to an intended application without changing the configuration of the processing section. Thus, it is not necessary to develop a new processing section for each application, thereby suppressing an increase in the management costs when, for example, making a change to the function. Since the function of the processing section is controlled by using information from outside, it is not necessary to change the internal configuration of the semiconductor device when, for example, enabling a function of the processing section that has been disabled. Since the input function identification information is encrypted, a user cannot easily decrypt the information to know the meaning thereof, and a user is prevented from making an unauthorized use of a decoding function for purposes other than the intended application.

At least a part of the function identification information may be encrypted, and the password may also be encrypted.

### Embodiment 3

A semiconductor device 300 according to Embodiment 3 of the present invention is an example of a semiconductor device that enables/disables a processing function based on information input from outside the semiconductor device 300 by means of communications via the Internet, or the like.

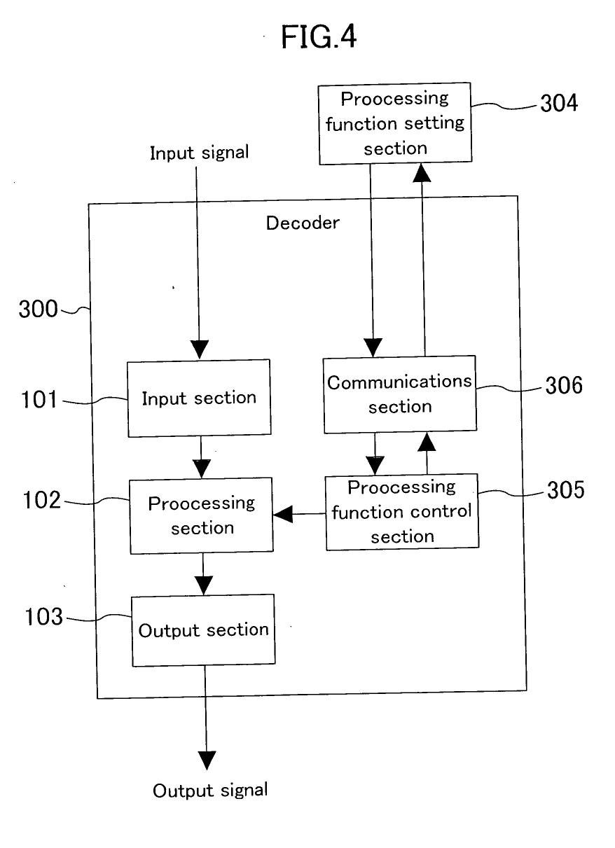

Referring to FIG. 4, the semiconductor device 300 includes the input section 101, the processing section 102, the output section 103, a processing function control section 305 and a communications section 306, wherein information for controlling the function of the processing section 102 is received from a processing function setting section 304 outside the semiconductor device 300 by means of communications via the Internet, or the like, through the communications section 306.

The processing function setting section 304 stores encrypted function identification information that indicates which decoding function of the processing section 102 should be enabled/disabled. When information unique to the semiconductor device 300 (e.g., a value in the version register, or the product number of the semiconductor device 300) is received from the processing function control section 305 of the semiconductor device 300 by means of communications, the processing function setting section 304 outputs the stored, encrypted function identification information to the processing function control section 305 according to the unique information. By setting the amount of information to be greater than the number of decoding functions of the processing section 102, a user is prevented from easily making an unauthorized use of a decoding function for purposes other than the intended application. The key information used for the encryption (decryption) of the function identification information may be predetermined information, or may be varied depending on the configuration of the processing section 102. For example, if the processing section 102 is implemented by software, a part or whole of the software may be used as the key information.

The processing function control section 305 outputs the unique information to the processing function setting section 304 by means of communications, and decrypts the encrypted function identification information received from the processing function setting section 304 so as to perform a function control operation for enabling one of Decoding Function 1 and Decoding Function 2 of the processing section 102 according to the value of the decrypted information.

With the semiconductor device 300 having such a configuration, an input signal is decoded into image data and sound data as follows.

According to the function identification information received from the processing function setting section 304 by means of communications, the processing function control section 305 performs a control operation so that a decoding function of the processing section 102 (e.g., Decoding Function 1) is enabled. If the input signal is a signal to be decoded by Decoding Function 1, the processing section 102 decodes the input signal into image data and sound data, which are output via the output section 103 to an external unit outside the semiconductor device 300.

As described above, also with the present embodiment, it is possible to realize a decoding function, etc., according to an intended application without changing the configuration of the processing section. Thus, it is not necessary to develop a new processing section for each application, thereby suppressing an increase in the management costs when, for example, making a change to the function.

Since information for controlling the processing section is input according to information unique to the semiconductor device 300 that is output via a communications path, it is easy to prevent a user from making an unauthorized use of a decoding function for purposes other than the intended application, or to lift the function limitations (thus to extend the functions) for a user who is newly permitted to use a predetermined decoding function. Since the input function identification information is encrypted, a user cannot easily decrypt the information to know the meaning thereof, and a user is prevented from making an unauthorized use of a decoding function for purposes other than the intended application.

The embodiments described above can be applied not only to a semiconductor device for decoding information, but also to any other suitable semiconductor device used in a DVD recorder, or the like, that performs a predetermined processing function to output the obtained signal, such as a semiconductor device for encoding information.

While the embodiments above are directed to examples where a signal recorded on a DVD disc is decoded by a DVD player, the present invention is not limited to this. For example, the present invention can be applied to a decoding operation, etc., used for audio/visual data distributed in digital TV broadcast, or the like, and can be applied to any suitable semiconductor device for performing various processing functions.

While the embodiments above are directed to examples where two different functions (Decoding Function 1 and Decoding Function 2) are used, the number of functions is not limited to this.

While Embodiments 2 and 3 are directed to semiconductor devices that encrypt the function identification information, etc., it is possible to perform the function control operation for enabling/disabling at least one of a plurality of decoding functions, without encrypting the information.

As described above, with the semiconductor device of the present invention, it is possible to easily realize an information processing function according to an intended application, and there is an advantageous effect that it is possible to suppress an increase in the management costs when, for example, making a change to the function. Thus, the present invention is useful as a semiconductor device, or the like, that has a plurality of processing functions (e.g., encoding and decoding of image data or sound data), and that performs one of the processing functions on the input data.

What is claimed is:

1. A semiconductor device including circuits formed on a semiconductor substrate, comprising:
a processing section having a plurality of information processing functions; and
a function control section for performing a function control operation so that at least one of the plurality of information processing functions of the processing section is enabled or disabled according to device identification information stored in the semiconductor device for identifying the semiconductor device.

2. The semiconductor device of claim 1, wherein the device identification information is a product number or a version number of the semiconductor device.

3. A semiconductor device including circuits formed on a semiconductor substrate, comprising:
a processing section having a plurality of information processing functions; and
a function control section for performing a function control operation so that at least one of the plurality of information processing functions of the processing section is enabled or disabled according to function permission information that is input from outside the semiconductor device while being encrypted at least partially.

4. The semiconductor device of claim 3, wherein the function control section performs the function control operation based on authentication data stored in advance in the semiconductor device and the function permission information.

5. The semiconductor device of claim 3, wherein:
the function permission information contains function identification information for identifying at least one of the plurality of information processing functions; and
the function control section enables at least one of the plurality of information processing functions of the processing section according to the function identification information.

6. A semiconductor device including circuits formed on a semiconductor substrate, comprising:
a processing section having a plurality of information processing functions;
a function control section for performing a function control operation so that at least one of the plurality of information processing functions of the processing section is enabled or disabled according to function permission information that is transmitted from outside the semiconductor device; and
a communications section for transmitting device identification information for identifying the semiconductor device to outside the semiconductor device and for receiving the function permission information transmitted from outside the semiconductor device according to the device identification information,
wherein the function control section performs the function control operation according to the function permission information received by the communications section.

7. The semiconductor device of claim 6, wherein at least a portion of the function permission information is encrypted.

8. The semiconductor device any one of claims 3 and 7, wherein key information used for encrypting the function permission information or for decrypting the encrypted function permission information is fixedly predetermined key information or is a part or whole of a program included in the processing section.

9. The semiconductor device any one of claims 1, 3 and 6, wherein the information processing functions include at least one of an encoding operation and a decoding operation.
